(19) United States
(12) Patent Application Publication
(10) Pub. No.: US 2026/0189236 A1
(43) Pub. Date: Jul. 2, 2026

(54) SUB SAMPLING PHASE LOCKED LOOP GAIN CORRECTION

(71) Applicant: MOTOROLA SOLUTIONS, INC., Chicago, IL (US)

(72) Inventors: Nir Corse, Rishon LeZion (IL); Josh Dorevitch, Yad Binyamin (IL); Mark Rozental, Gedera (IL)

(21) Appl. No.: 19/004,868

(22) Filed: Dec. 30, 2024

(51) Int. Cl. H03L 7/099; H03L 7/093

(52) U.S. Cl. CPC H03L 7/099; H03L 7/093

(57) ABSTRACT

Examples, aspects, and instances provide gain correction for a sub-sampling phase-locked loop (SSPLL) architecture. One example SSPLL architecture includes a reference phase-locked loop (RPLL) generator, a delay module, a phase detector, a phase frequency detection loop, and an electronic processor. The electronic processor is configured to operate the SSPLL architecture in a phase frequency detection operating mode to estimate an internal voltage-controlled oscillator (IVCO) gain based on a current flowing through the phase frequency detection loop, operate the SSPLL architecture in a gain estimation loop to estimate a sub-sampling phase detection (SSPD) gain value based the phase detector output, calculate a correction value based on the IVCO gain and the SSPD gain value, and operate the SSPLL architecture in an operating SSPLL loop to apply the correction value to the phase detector.

### BACKGROUND OF THE INVENTION

A phase-locked loop (PLL) is a control system that generates an output signal whose phase is related to the phase of an input signal. In sub-sampling phase-locked loops (SSPLLs), an auxiliary loop is implemented to acquire the frequency using a phase frequency detector (PFD). A primary loop uses a phase detector to lock onto the phase by sampling a voltage-controlled oscillator signal.

### BRIEF DESCRIPTION OF THE SEVERAL VIEWS OF THE DRAWINGS

The accompanying figures, where like reference numerals refer to identical or functionally similar elements throughout the separate views, together with the detailed description below, are incorporated in and form part of the specification, and serve to further illustrate examples, instances, and/or aspects of concepts that include the claimed subject matter, and explain various principles and advantages of examples, instances, and/or aspects.

FIG. 1 is a block diagram of a subsampling PLL, according to one example.

FIG. 2 is a graph illustrating the noise within the SSPLL architecture of FIG. 1 represented multiplied by a transfer function on a logarithmic scale.

FIG. 3 is a graph illustrating the impact of variation of an SSPLL unity frequency on IVCO noise rejection by SSPLL at 1 MHz offset.

FIG. 4 is a graph illustrating the total SSPLL phase noise (PN) vs. rejection of IVCO noise by SSPLL.

FIG. 5 is a graph further illustrating the IVCO noise contribution closed loop response as a function of phase detector gain G_{PD} variation and IVCO gain Kᵥ variation.

FIG. 6 is a block diagram of a controller for the SSPLL architecture of FIG. 1, according to one example.

FIGS. 7A-7B illustrates a flowchart of a method for calibrating the SSPLL architecture of FIG. 1 according to some examples.

FIG. 8 illustrates an example of the SSPLL architecture of FIG. 1 configured in a phase frequency detection operating mode.

FIG. 9 illustrates an example of the SSPLL architecture of FIG. 1 configured in a subsampling phase detector gain estimation operating mode.

FIGS. 10A-10B illustrate characteristics of the sub sampling phase detector output currents vs. variable delay module code words.

FIG. 11 illustrates an example of the SSPLL architecture of FIG. 1 configured in an SSPLL operating mode.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of examples.

The system, apparatus, and method components have been represented where appropriate by conventional symbols in the drawings, showing only those specific details that are pertinent to understanding the examples, instances, and aspects illustrated so as not to obscure the disclosure with details that will be readily apparent to those of ordinary skill in the art having the benefit of the description herein.

### DETAILED DESCRIPTION OF THE INVENTION

A sub-sampling phase-locked loop (SSPLL) as described herein include a dual-loop architecture including a first loop and a second loop for a calibration procedure. The first loop is implemented to acquire the frequency using a phase frequency detector. The second loop implements a phase detector to lock onto the phase by subsampling a voltage-controlled oscillator's clock using a reference clock.

One example provides a phase frequency detection loop including a reference phase-locked loop generator, a phase frequency detector, a charge pump, a loop filter, an internal voltage-controlled oscillator (IVCO), a buffer, and an N divider. The circuit includes a gain estimation loop including the phase frequency detection loop, a delay module, a sampler, a gain module, a resistive load, and an analog-digital converter. The circuit includes an operating sub-sampling phase-locked loop (SSPLL) loop including the reference phase-locked loop generator, the sampler, the gain module, the loop filter, the internal voltage-controlled oscillator, and the buffer. The circuit also includes a first switch between the reference phase-locked loop generator and the sampler, a second switch between the gain module and the loop filter, a third switch between the gain module and the resistive load, a fourth switch between an input of the internal voltage-controlled oscillator and the analog-digital converter, and an electronic processor. The electronic processor is configured to lock a frequency of the internal voltage-controlled oscillator, estimate an IVCO gain while in the phase frequency detection loop, estimate a sub-sampling phase detection gain value while in the gain estimation loop, estimate a correction value based on the IVCO gain and the sub-sampling phase detection gain value, apply the correction value to the gain module, and set the circuit to the operating SSPLL loop.

Another example provides a sub-sampling phase-locked loop (SSPLL) architecture including a reference phase-locked loop (RPLL) generator, a delay module configured to receive an output of the RPLL generator and apply a delay to the output of the RPLL generator to generate a delayed output, a phase detector configured to receive the delayed output from the delay module and apply a phase detector gain to the delayed output to generate a phase detector output, a phase frequency detection loop, and an electronic processor. The electronic processor is configured to operate the SSPLL architecture in a phase frequency detection operating mode, wherein, in the phase frequency detection operating mode, the electronic processor is configured to estimate an internal voltage-controlled oscillator (IVCO) gain based on a current flowing through the phase frequency detection loop, operate the SSPLL architecture in a gain estimation loop, wherein, in the gain estimation loop, the electronic processor is configured to estimate a sub-sampling phase detection (SSPD) gain value based the phase detector output, calculate a correction value based on the IVCO gain and the SSPD gain value, and operate the SSPLL architecture in an operating SSPLL loop, wherein, in the operating SSPLL loop, the electronic processor is configured to apply the correction value to the phase detector.

Another example provides a method for controlling an SSPLL architecture, the method including: operating the SSPLL architecture in a phase frequency detection operating mode, estimating, while in the phase frequency detection operating mode, an internal voltage-controlled oscillator (IVCO) gain based on a current flowing through a phase frequency detection loop, operating the SSPLL architecture in a gain estimation loop, estimating a sub-sampling phase detection (SSPD) gain value based an output of a phase detector, calculating a correction value based on the IVCO gain and the SSPD gain value, applying the correction value to the phase detector, and operating the SSPLL architecture in an operating SSPLL loop.

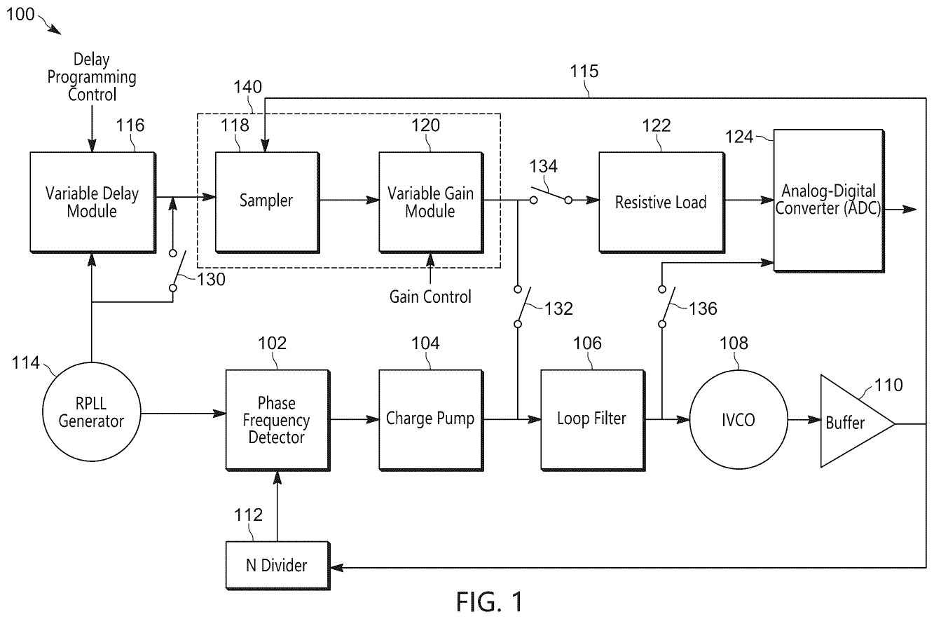

FIG. 1 illustrates an SSPLL architecture 100 according to one example. The SSPLL architecture 100 may be implemented to generate a frequency source for a device, such as for a receiver mixer or a transmitter. In some instances, the receiver mixer and transmitter in used in a portable communication, for example a land mobile radio. The example SSPLL architecture 100 of FIG. 1 includes a phase frequency detector 102, a charge pump 104, a loop filter 106, an internal voltage-controlled oscillator (IVCO) 108, a buffer 110, and an N-divider 112. The N-divider 112 may be a delta-sigma controlled fractional divider. The SSPLL architecture 100 also includes a reference phase-locked loop (RPLL) generator 114, a variable delay module 116, a sampler 118, a variable gain module 120, a resistive load 122, and an analog-digital converter (ADC) 124. The sampler 118 and the variable gain module 120 collectively form a subsampling phase detector 140. The variable gain module 120 may be a transconductance (Gm) gain stage with voltage input and current output. The RPLL generator 114 may generate a reference frequency for the SSPLL architecture 100. The SSPLL architecture 100 includes a first switch 130 connected between the RPLL generator 114 and the sampler 118. The SSPLL architecture 100 includes a second switch 132 connected between the variable gain module 120 and the loop filter 106. The SSPLL architecture 100 includes a third switch 134 connected between the variable gain module 120 and the resistive load 122. The SSPLL architecture 100 includes a fourth switch 136 connected between the loop filter 106 and the ADC 124.

During operation, the phase frequency detector 102 compares the reference frequency from the RPLL generator 114 with the divided IVCO 108 frequency from the N-divider 112. The phase frequency detector 102 then controls the charge pump 104 current. The current from the charge pump 104 is applied to the loop filter 106. The loop filter 106 outputs a voltage that controls the IVCO 108 frequency. The IVCO 108 frequency is applied to the buffer 110. The output of the buffer 110 is applied to the N-divider 112. These operations collectively form a first loop (e.g., an auxiliary loop). The output of the buffer 110 is also applied to the subsampling phase detector 140 (e.g., the sampler 118). While the first loop is operating, the phase frequency detector 102 acquires the operating frequency of the first loop. The loop bandwidth of the first loop may be, for example, 1 MHz.

The SSPLL architecture 100 also operates in a gain estimation mode for the subsampling phase detector 140. For example, the clock from the RPLL generator 114 is applied to the variable delay module 116. The variable delay module 116 delays the RPLL signal from the RPLL generator 114 according to a specific programmed delay (when the first switch 130 is not conducting). The output of the buffer 110 is provided to the sampler 118 (as a clock 115). When the second switch 132 is not conducting and the third switch 134 is conducting, output current from the variable gain module 120 is applied to the resistive load 122, developing a voltage on the resistive load 122. The voltage of the resistive load 122 is applied to the ADC 124, which converts the voltage of the resistive load 122 to a digital value.

The SSPLL architecture 100 also operates in a subsampling mode. For example, the clock from the RPLL generator 114 is applied to the sampler 118 (when the first switch 130 is conducting). The sampler 118 samples the buffered clock from the buffer 110 and provides an output voltage signal to the variable gain module 120. The variable gain module 120 provides a current to the loop filter 106 (when the second switch 132 is conducting) according to the transconductance gain of the variable gain module 120. Voltage from loop filter 106 then provides a tuning voltage to the IVCO 108. The output clock from the IVCO 108 is buffered by the buffer 110.

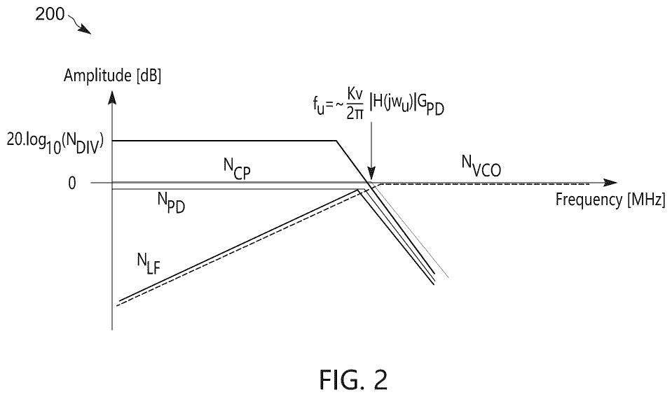

In the SSPLL architecture 100, each component generates noise. For example, the noise of each clock (e.g., the IVCO 108 and the RPLL generator 114) has a specific transfer function to the output of the SSPLL architecture 100. FIG. 2 illustrates the noise transfer functions of the phase-locked loop output and various components within the SSPLL architecture 100. In the example provided in FIG. 2, the noise is represented in a form where it is multiplied by a transfer function and presented on a logarithmic scale. In the graph 200, N_{VCO} represents the noise at the phase-locked loop output caused by the IVCO 108. As shown in FIG. 2, the IVCO noise transfer function to the phase-locked loop output is high pass. The IVCO noise above the phase-locked loop unity gain frequency fᵤ is not changed by the phase-locked loop transfer function. The IVCO noise below the phase-locked loop unity gain frequency fᵤ is reduced (e.g., attenuated) by the phase-locked loop transfer function.

Some examples described herein provide a unity frequency fᵤ that is dependent on the IVCO 108 gain K_{VCO} [MHz/V], the phase detector gain, and the loop filter PVT variations. Reducing variations in the loop gain and the unity frequency fᵤ also reduce noise variation within the loop. To achieve predictable and consistent phase-locked loop noise performance, the phase-locked loop unity gain frequency fᵤ may be desired to be constant over processing, voltage, and temperature (PVT) variations. Accordingly, by measuring parameters of the SSPLL architecture 100 such as IVCO gain and subsampling phase detector gain, a phase detector gain may be identified to keep the phase-locked loop bandwidth constant. Equation (1) provides one example of fᵤ:

$${f}_{u} = ∼ \frac{{K}_{v}}{2 π} \vert H ( {jw}_{u} ) \vert {G}_{PD} \qquad Equation ( 1 )$$

where:
Kᵥ is the IVCO gain in MHz/V;
H(jwᵤ) is the transfer function; and
G_{PD} is the gain of the phase detector in mA/pi.

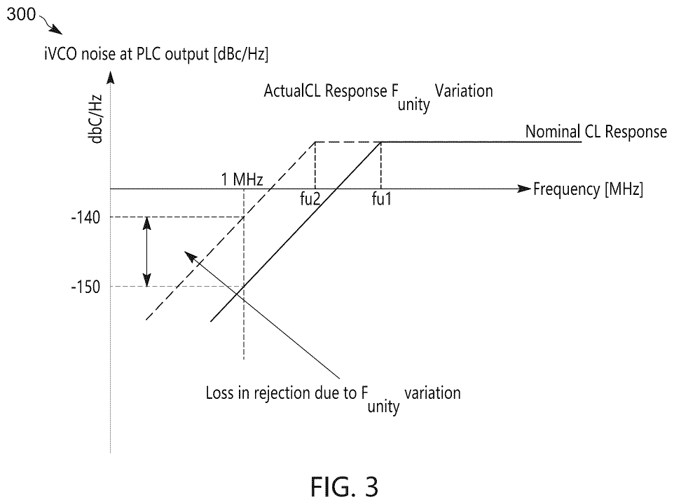

FIG. 3 is a graph 300 illustrating an impact of variation of the unity frequency fᵤ. In some instances, variations in the unity frequency fᵤ result in variation in IVCO noise rejection at the phase-locked loop output. In FIG. 3, nominal phase-locked loop bandwidth frequency fᵤ₁ results in approximately −150 dBc/Hz IVCO noise at the phase-locked loop output. The noise due to PVT variation, or the phase-locked loop bandwidth frequency fᵤ₂, results in −140 dBc/Hz IVCO noise at the phase-locked loop output, causing 10 dB of noise degradation.

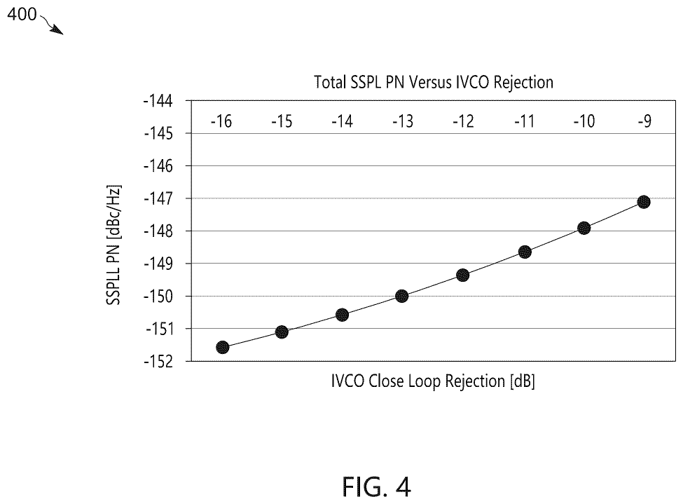

FIG. 4 is a graph 400 illustrating the total SSPLL phase noise (PN) compared to rejection of the IVCO noise. In the example shown in the graph 400, IVCO rejection reduces below −13 dB due to variation in the phase-locked loop unity gain frequency fᵤ, and the total SSPLL PN is higher than −150 dBc/Hz. A 6 dB variation in the IVCO noise rejection (at 1 MHz offset from the carrier) by phase-locked loop results in approximately 3.5 dB variation in the total SSPLL PN at 1 MHz offset.

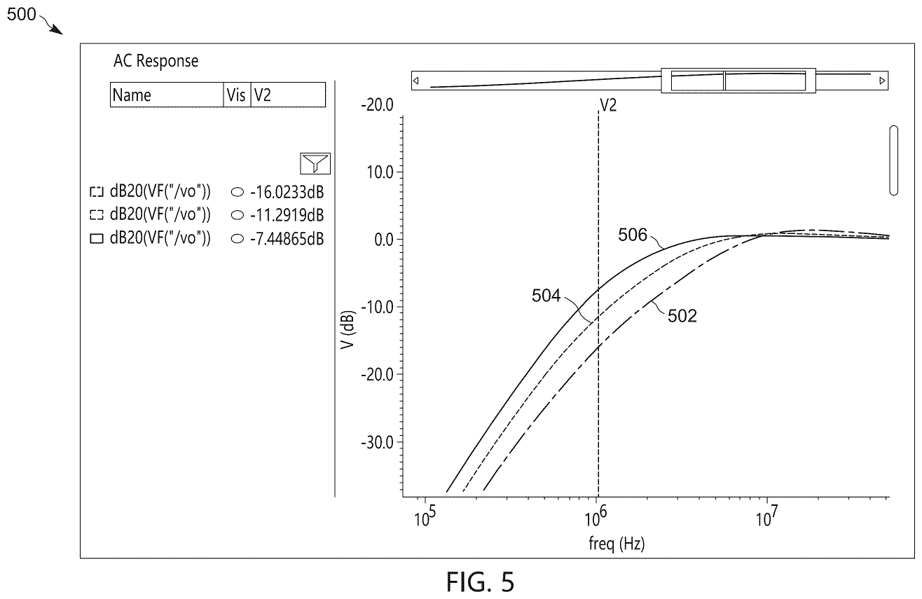

FIG. 5 is a graph 500 further illustrating the IVCO noise transfer function to the phase-locked loop output as a function of phase detector gain G_{PD} variation and IVCO gain Kᵥ variation. In the example shown, a first function 502 shows a typical IVCO closed loop response having approximately 16 dB IVCO noise rejection at 1 MHz offset. In the first function 502, phase detector gain G_{PD} has a value of approximately 10 mA/pi and Kᵥ has a value of approximately 180 MHz/V. A second function 504 shows an approximately 40% variation in the value of G_{PD}. In the second function 504, Kᵥ has a value of approximately 180 MHz/V, and a reduction of approximately 4.7 dB in the IVCO closed loop rejection is observed. A third function 506 shows an approximately 40% PVT variation (reduction) in the value of G_{PD} and approximately 50% variation in the value of IVCO gain Kᵥ. A reduction of approximately 8.6 dB in the IVCO closed loop rejection is observed.

Accordingly, examples described herein, among other things, constant and predictable phase noise at the output of the SSPLL architecture 100 to keep the phase-locked loop unity gain frequency fᵤ as constant as possible. Parameters that influence the phase-locked loop unity gain frequency fᵤ include the IVCO gain Kᵥ and the subsampling phase detector gain G_{PD}. In some instances, two separate current loops within the SSPLL architecture 100 are controlled to measure a subsampling phase detector gain G_{PD} and IVCO gain Kᵥ. The phase detector gain G_{PD} and IVCO gain Kᵥ may be measured and phase detector gain G_{PD} can be corrected to achieve a desired phase loop-locked bandwidth with desired noise.

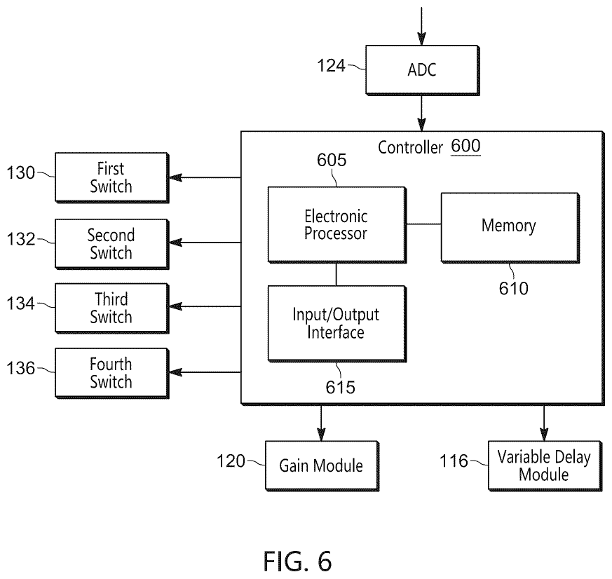

FIG. 6 is a block diagram of a controller 600 for the SSPLL architecture 100 according to one example. In the illustrated example, the controller 600 includes an electronic processor 605 (for example, a microprocessor or another electronic device). The electronic processor 605 may be electrically connected to a memory 610 and an input/output (I/O) interface 615. In some instances, the controller 600 may include fewer or additional components in configurations different from that illustrated in FIG. 6. In some instances, the controller 600 performs additional functionality than the functionality described below.

The memory 610 includes read only memory (ROM), random access memory (RAM), other non-transitory computer-readable media, or a combination thereof. The electronic processor 605 is configured to receive data from the memory 610 and execute, among other things, instructions stored in the memory 610. In some instances, the electronic processor 605 executes instructions stored in the memory 610 to perform methods described herein.

The I/O interface 615 establishes connections between components of the SSPLL architecture 100 connected to the controller 600. For example, the I/O interface 615 may include connectors or ports to establish wired connections to components of the SSPLL architecture 100. In another example, the I/O interface 615 establishes wireless connections to components of the SSPLL architecture 100. In some implementations, the controller 600 is connected to, for example, the first switch 130, the second switch 132, the third switch 134, the fourth switch 136, the N-divider 112, the variable delay module 116, the variable gain module 120, and the ADC 124.

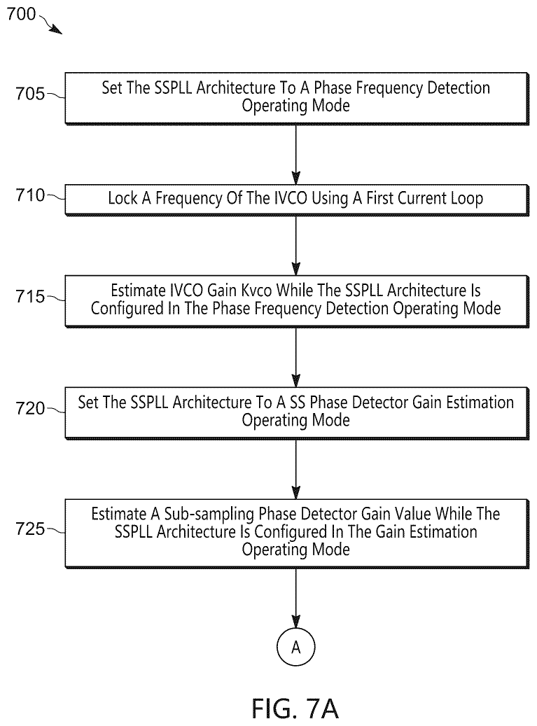

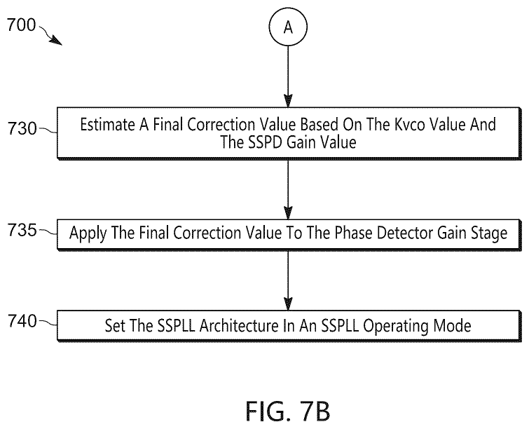

FIGS. 7A-7B illustrates a block diagram of a method 700 for calibrating the SSPLL architecture 100 according to some examples. The method 700 is described as being executed by the controller 600 and, in particular, by the electronic processor 605. However, in some instances, the method 700 may be performed by another device (for example, another computer or device within or associated with the SSPLL architecture 100). Additionally, while the process blocks illustrated in FIGS. 7A-7B provide one example of a method described herein, it is understood that some blocks may be removed, added, combined, reordered, or modified without departing from the spirit of the present disclosure.

At block 705, the electronic processor 605 sets the SSPLL architecture 100 to a phase frequency detection operating mode. For example, the electronic processor 605 controls the first switch 130, the second switch 132, and the third switch 134 to open positions such that current does not flow through the first switch 130, the second switch 132 or the third switch 134. The electronic processor 605 controls the fourth switch 136 to a closed position such that current does flow through the fourth switch 136. This configuration of the first switch 130, the second switch 132, the third switch 134 and the fourth switch 136 set the SSPLL architecture 100 within a phase frequency detection loop.

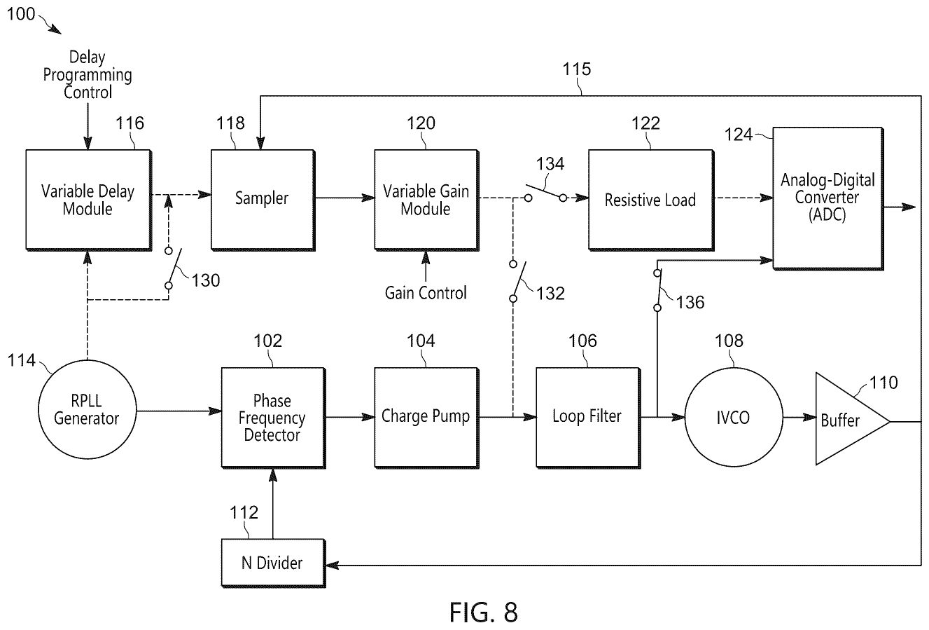

FIG. 8 illustrates an example of the SSPLL architecture 100 configured in the phase frequency detection loop. In the example of FIG. 8, dotted lines indicate that current does not flow through the designated paths. As seen in FIG. 8, current flows in a loop through the phase frequency detector 102, the charge pump 104, the loop filter 106, the IVCO 108, the buffer 110, and the N-divider 112, back to the phase frequency detector 102.

At block 710, the electronic processor 605 locks a frequency of the IVCO 108. For example, the electronic processor 605 sets the frequency of the IVCO 108 to a desired output frequency by programming the integer and/or fractional value of N-divider 112.

At block 715, the electronic processor 605 estimates the IVCO gain Kᵥ while the SSPLL architecture 100 is in the phase frequency detection operating mode. In some instances, the electronic processor 605 estimates the IVCO gain Kᵥ by locking (e.g., setting) the IVCO 108 in two different frequencies and analyzing the voltage at the loop filter 106 output when the fourth switch 136 is conducting current. The voltage at the loop filter 106 output may be sampled by the ADC 124 and converted to digital format. The digital value indicative of the voltage at the loop filter 106 is output by the ADC 124 to the electronic processor 605. By way of example, the electronic processor 605 sets the frequency of the IVCO 108 to a first frequency value f₁. The electronic processor 605 senses a first voltage V₁ at the loop filter 106 output when the fourth switch 136 is conducting current. The electronic processor 605 then sets the frequency of the IVCO 108 to a second frequency value f₂. The electronic processor 605 senses a second voltage V₂ at the loop filter 106 output when the fourth switch 136 is conducting current. The electronic processor 605 calculates the correction value Kᵥ using the first frequency value f₁, the second frequency value f₂, the first voltage V₁ and the second voltage V₂ according to Equation (1):

$${K}_{v} = \frac{{f}_{2} - {f}_{1}}{{V}_{2} - {V}_{1}} \qquad Equation ( 1 )$$

At block 720, the electronic processor 605 sets the SSPLL architecture 100 to a subsampling phase detector gain estimation operating mode. For example, the electronic processor 605 controls the first switch 130, the second switch 132 and the fourth switch 136 to open positions such that the current does not flow through the first switch 130, the second switch 132, or the fourth switch 136. The electronic processor 605 controls the third switch 134 to a closed position such that current does flow through the third switch 134. When the first switch 130, the second switch 132, the third switch 134 and the fourth switch 136 are in these positions (or states), the SSPLL architecture 100 is configured in a subsampling phase detector gain estimation loop.

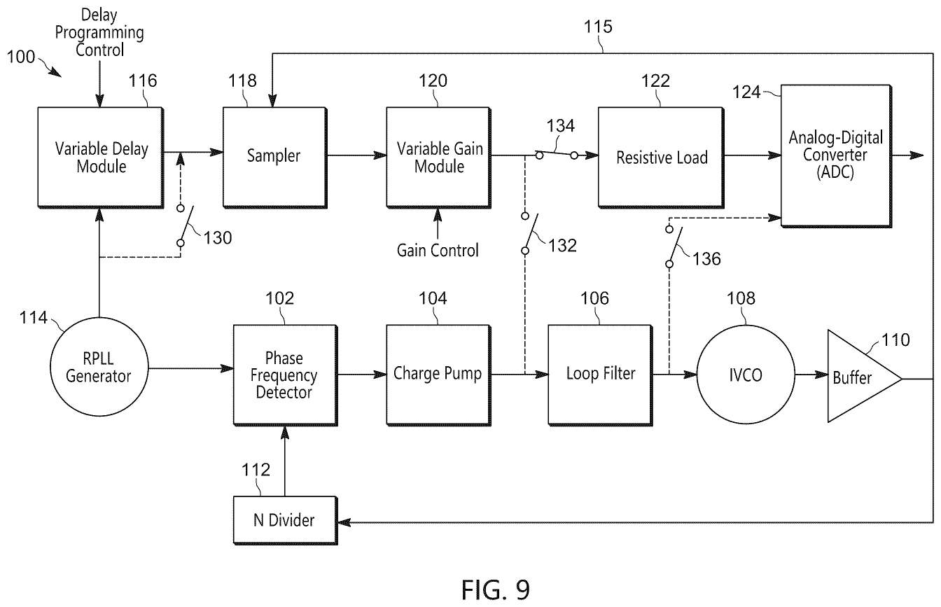

FIG. 9 illustrates an example of the SSPLL architecture 100 configured in a gain estimation loop. In the example of FIG. 9, dotted lines indicate that current does not flow through the designated paths. As seen in FIG. 9, current flows through the RPLL generator 114, the variable delay module 116, the sampler 118, the variable gain module 120, and the resistive load 122 to the ADC 124. Additionally, current flows in a loop through the phase frequency detector 102, the charge pump 104, the loop filter 106, the IVCO 108, the buffer 110, and the N-divider 112, back to the phase frequency detector 102. An output of the buffer 110 is provided to the sampler 118. As can be noted, the components of the phase frequency detection loop are still active when the SSPLL architecture 100 is set to the gain estimation loop.

At block 725, the electronic processor 605 estimates a sub-sampling phase detection (SSPD) gain value G_{PD} while the SSPLL architecture 100 is configured in the gain estimation operating mode. In one example, the SSPD gain value G_{PD} may be estimated by analyzing the derivative of the output current Io of the variable gain module 120 (e.g., the output current of the subsampling phase detector 140) with respect to change in phase Ø at near-zero current values. The output current Io of the variable gain module 120 is applied to resistive load 122. Accordingly, the output of the resistive load 122 is a voltage that is proportional to the output current Io of the variable gain module 120. The output of the resistive load 122 may be sampled and converted to digital format by the ADC 124. The digital output of the ADC 124 indicative of the output current Io of the variable gain module 120 is provided to the electronic processor 605. To generate the derivative of the output current Io of the variable gain module 120, the variable delay module 116 applies a delay to the signal from the RPLL generator 114. The delay may be considered one or more “steps”. The electronic processor 605 measures the output current Io of the variable gain module 120 with the applied delay from the variable delay module 116. Once the output current Io is measured, the electronic processor 605 may control the variable delay module 116 to apply a new delay, thereby incrementing (or decrementing) the delay. The variable delay module 116 may be implemented as a digital to time converter (DTC), a delayed locked loop (DLL), or some other variable delay circuit. This process is repeated over a plurality of delay values, thereby varying the delay applied to the signal from the RPLL generator 114. As the IVCO 108 remains at a constant value, altering the delay of the signal from the RPLL generator 114 results in changing current and voltage values output by the variable gain module 120. The electronic processor 605 may calculate the SSPD gain value according to Equation (2):

$$SSPD Gain = \frac{{di}_{o}}{d ∅} = \frac{\partial {i}_{o}}{\partial t} \frac{\partial t}{\partial ∅} = \frac{1}{2 π {f}_{ref}} \frac{\partial {i}_{o}}{\partial t} \qquad Equation ( 2 )$$

### Where:

diₒ is the change in output current of the variable gain module 120;
dØ is the change in the phase of the output current of the variable gain module 120;
∂t is the differential of time t; and
f_{ref} is a reference frequency. In some instances, f_{ref} is the frequency at the output of the
RPLL generator 114.

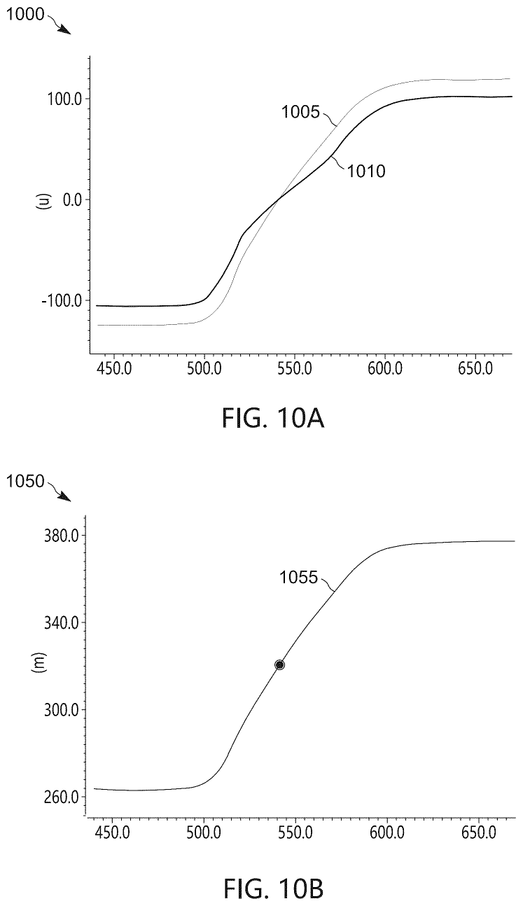

FIGS. 10A-10B illustrate characteristics of the variable gain module 120 compared to current code words. In the example shown, FIG. 10A includes a graph 1000 of the output current Io of the variable gain module 120 on the y-axis and the code words on the x-axis. In a first function 1005, the SSPD gain has a value of 0100. In a second function 1010, the SSPD gain G_{PD} has a value of 0001. FIG. 10B illustrates a graph 1050 of the output voltage Vo of the variable gain module 120 on the y-axis and the code words on the x-axis. A third function 1055 corresponds to the SSPD gain value of 0100. As can be observed in the graph 1000, as the SSPD gain G_{PD} increases, the slope

$$\frac{d {i}_{o}}{d ∅}$$

also increases.

With reference to FIG. 7B, at block 730, the electronic processor 605 estimates a correction value based on the IVCO gain Kᵥ and the SSPD gain value G_{PD}. By way of one example, the electronic processor 605 inputs the IVCO gain value Kv and the SSPD gain value G_{PD} to an algorithm, such as an equation or a series of equations, to calculate the correction value. For example, the electronic processor 605 may calculate an amount of error Error[%] within the SSPLL architecture 100 based on the estimated IVCO gain Kv, the estimated SSPD gain value, an expected Kv value, and an expected SSPD gain value, according to Equation (3):

$$Error [ \% ] = \frac{( {Kv}_{Ideal} * {SSPD}_{Ideal} - {Kv}_{est} * {SSPD}_{est} )}{{Kv}_{ideal} * {SSPD}_{ideal}} \qquad Equation ( 3 )$$

where:
Kv_{ideal} is an expected or ideal value of the correction value Kᵥ;
Kvₑₛₜ is the estimated IVCO gain Kᵥ obtained at block 715;
SSPD_{ideal} is an expected or ideal SSPD gain value; and
SSPDₑₛₜ is the estimated SSPD gain value obtained at block 725. The expected SSPD gain value and the expected correction value may be desired values input by a user of the SSPLL architecture 100.

Next, to determine the amount of correction Corrₛₜₑₚₛ to be added to an initial value of the applied phase detector gain PDᵢₙᵢₜ to achieve the desired phase detector gain PD_{gain}, the electronic processor 605 divides the calculated amount of error Error[%] by the percentage change in steps from the variable delay module 116, according to Equation (4):

$$C {orr}_{Steps} = \frac{Error [ \% ]}{Δ [ \frac{\%}{Step} ]} \qquad Equation ( 4 )$$

The electronic processor 605 adds the correction Corrₛₜₑₚₛ to the initial value of the phase detector gain PDᵢₙᵢₜ to obtain the phase detection gain PD_{gain}, according to Equation (5):

$${PD}_{gain} = {PD}_{init} + C {orr}_{Steps}$$

At block 735, the electronic processor 605 applies the correction value PD_{gain} to the variable gain module 120 of the subsampling phase detector 140. For example, the electronic processor 605 transmits a signal to the variable gain module 120 indicative of the calculated phase detection gain PD_{gain}. The variable gain module 120 updates a stored gain value to the calculated phase detection gain PD_{gain}.

At block 740, the electronic processor 605 sets the SSPLL architecture 100 in an SSPLL operating mode. For example, the electronic processor 605 controls the third switch 134 and the fourth switch 136 to open positions such that current does not flow through the third switch 134 and the fourth switch 136. The electronic processor 605 controls the first switch 130 and the second switch 132 to a closed position such that current does flow through the first switch 130 and the second switch 132. This configuration of the first switch 130, the second switch 132, the third switch 134 and the fourth switch 136 configures the SSPLL architecture 100 in an operating SSPLL loop, thereby ending calibration of the SSPLL architecture 100.

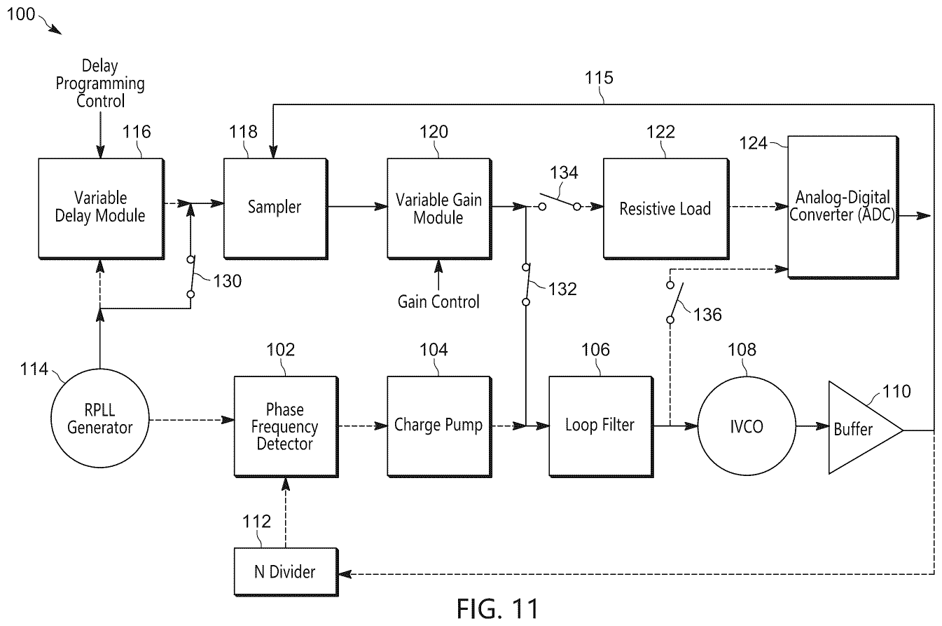

FIG. 11 illustrates an example of the SSPLL architecture 100 configured in an operating SSPLL loop. In the example of FIG. 11, dotted lines indicate that current does not flow through the designated paths. As seen in FIG. 11, current flows from the RPLL generator 114 to the sampler 118, through the variable gain module 120, through the loop filter 106, through the IVCO 108, and through the buffer 110. An output of the buffer 110 is provided to the sampler 118. When in the operating loop, the phase frequency detector 102, the charge pump 104, and the n-divider 112 are not activated for operation. In some instances, the phase frequency detector 102, the n-divider 112 and/or the charge pump 104 are electrically disconnected from the remainder of the SSPLL architecture 100, such as by one or more switches. In the operating loop, the subsampling phase detector 140 operates using the calculated phase detection gain PD_{gain}.

As should be apparent from this detailed description above, the operations and functions of the electronic computing device are sufficiently complex as to require their implementation on a computer system, and cannot be performed, as a practical matter, in the human mind. Electronic computing devices such as set forth herein are understood as requiring and providing speed and accuracy and complexity management that are not obtainable by human mental steps, in addition to the inherently digital nature of such operations (e.g., a human mind cannot interface directly with RAM or other digital storage and cannot transmit signals to control electronic switches, among other features and functions set forth herein).

In the foregoing specification, specific examples have been described. However, one of ordinary skill in the art appreciates that various modifications and changes may be made without departing from the scope of the invention as set forth in the claims below. Accordingly, the specification and figures are to be regarded in an illustrative rather than a restrictive sense, and all such modifications are intended to be included within the scope of present teachings.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.
in this document, relational terms such as first and second, top and bottom, and the like may be used solely to distinguish one entity or action from another entity or action without necessarily requiring or implying any actual such relationship or order between such entities or actions. The terms “comprises,” “comprising,” “has,” “having,” “includes,” “including,” “contains,” “containing,” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a,” “has . . . a,” “includes . . . a,” “contains . . . a” does not, without more constraints, preclude the existence of additional identical elements in the process, method, article, or apparatus that comprises, has, includes, contains the element. Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

Also, it should be understood that the illustrated components, unless explicitly described to the contrary, may be combined or divided into separate software, firmware, and/or hardware. For example, instead of being located within and performed by a single electronic processor, logic and processing described herein may be distributed among multiple electronic processors. Similarly, one or more memory modules and communication channels or networks may be used even if examples described or illustrated herein have a single such device or element. Also, regardless of how they are combined or divided, hardware and software components may be located on the same computing device or may be distributed among multiple different devices. Accordingly, in this description and in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively.

It will be appreciated that some examples may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an example may be implemented as a computer-readable storage medium having computer readable code stored thereon for programming a computer (for example, comprising a processor) to perform a method as described and claimed herein. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The terms “substantially,” “essentially,” “approximately,” “about” or any other version thereof, are defined as being close to as understood by one of ordinary skill in the art, and in one non-limiting example the term is defined to be within 10%, in another example within 5%, in another example within 1% and in another example within 0.5%. The term “one of,” without a more limiting modifier such as “only one of,” and when applied herein to two or more subsequently defined options such as “one of A and B” should be construed to mean an existence of any one of the options in the list alone (e.g., A alone or B alone) or any combination of two or more of the options in the list (e.g., A and B together).

A device or structure that is “configured” in a certain way is configured in at least that way, but may also be configured in ways that are not listed.

The terms “coupled,” “coupling” or “connected” as used herein can have several different meanings depending on the context in which these terms are used. For example, the terms coupled, coupling, or connected can have a mechanical or electrical connotation. For example, as used herein, the terms coupled, coupling, or connected can indicate that two elements or devices are directly connected to one another or connected to one another through intermediate elements or devices via an electrical element, electrical signal or a mechanical element depending on the particular context.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it may be seen that various features are grouped together in various examples for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separately claimed subject matter.

We claim:

1. A circuit comprising:
a phase frequency detection loop including:
a reference phase-locked loop generator;
a phase frequency detector;
a charge pump;
a loop filter;
an internal voltage-controlled oscillator (IVCO);
a buffer; and
an N divider;
a gain estimation loop comprising:
the phase frequency detection loop;
a delay module;
a sampler;
a gain module;
a resistive load; and
an analog-digital converter;
an operating sub-sampling phase-locked loop (SSPLL) loop comprising:
the reference phase-locked loop generator;
the sampler;
the gain module;
the loop filter;
the internal voltage-controlled oscillator; and
the buffer;
a first switch between the reference phase-locked loop generator and the sampler;
a second switch between the gain module and the loop filter;
a third switch between the gain module and the resistive load;
a fourth switch between an input of the internal voltage-controlled oscillator and the analog-digital converter, and
an electronic processor configured to:
lock a frequency of the internal voltage-controlled oscillator;
estimate an IVCO gain while in the phase frequency detection loop;
estimate a sub-sampling phase detection gain value while in the gain estimation loop;
estimate a correction value based on the IVCO gain and the sub-sampling phase detection gain value;
apply the correction value to the gain module; and
set the circuit to the operating SSPLL loop.

2. The circuit of claim 1, further comprising:
a first switch between the reference phase-locked loop generator and the sampler;
a second switch between the gain module and the loop filter;
a third switch between the gain module and the resistive load; and
a fourth switch between the internal voltage-controlled oscillator input and the analog-digital converter.

3. The circuit of claim 2, wherein the electronic processor is further configured to:
set the circuit to the phase frequency detection loop by controlling the first switch, the second switch, and the third switch to an open position and controlling the fourth switch to a closed position.

4. The circuit of claim 2, wherein the electronic processor is further configured to:
set the circuit to the gain estimation loop by controlling the first switch, the second switch, and the fourth switch to an open position and controlling the third switch to a closed position.

5. The circuit of claim 2, wherein the electronic processor is further configured to:
set the circuit to the operating SSPLL loop by controlling the first switch and the second switch to a closed position and controlling the third switch and the fourth switch to an open position.

6. A sub-sampling phase-locked loop (SSPLL) architecture comprising:
a reference phase-locked loop (RPLL) generator;
a delay module configured to receive an output of the RPLL generator and apply a delay to the output of the RPLL generator to generate a delayed output;
a phase detector configured to receive the delayed output from the delay module and apply a phase detector gain to the delayed output to generate a phase detector output;
a phase frequency detection loop; and
an electronic processor configured to:
operate the SSPLL architecture in a phase frequency detection operating mode, wherein, in the phase frequency detection operating mode, the electronic processor is configured to estimate an internal voltage-controlled oscillator (IVCO) gain based on a current flowing through the phase frequency detection loop;
operate the SSPLL architecture in a gain estimation loop, wherein, in the gain estimation loop, the electronic processor is configured to estimate a sub-sampling phase detection (SSPD) gain value based the phase detector output;
calculate a correction value based on the IVCO gain and the SSPD gain value; and
operate the SSPLL architecture in an operating SSPLL loop, wherein, in the operating SSPLL loop, the electronic processor is configured to apply the correction value to the phase detector.

7. The SSPLL architecture of claim 6, further comprising:
an analog-digital converter (ADC) connected to an output of the phase detector and connected to the phase frequency detection loop,
a first switch between the reference phase-locked loop (RPLL) generator and the phase detector;
a second switch between the phase detector and the phase frequency detection loop;
a third switch between the phase detector and the ADC; and
a fourth switch between the phase frequency detection loop and the ADC.

8. The SSPLL architecture of claim 7, wherein the electronic processor is further configured to:
operate the SSPLL architecture in the phase frequency detection operating mode by controlling the first switch, the second switch, and the third switch to an open position and controlling the fourth switch to a closed position.

9. The SSPLL architecture of claim 7, wherein the electronic processor is further configured to:
operate the SSPLL architecture in the gain estimation loop by controlling the first switch, the second switch, and the fourth switch to an open position and controlling the third switch to a closed position.

10. The SSPLL architecture of claim 7, wherein the electronic processor is further configured to:
operate the SSPLL architecture in the operating SSPLL loop by controlling the first switch and the second switch to a closed position and controlling the third switch and the fourth switch to an open position.

11. The SSPLL architecture of claim 6, wherein the phase frequency detection loop includes an internal voltage-controlled oscillator (IVCO).

12. The SSPLL architecture of claim 11, wherein, to estimate the IVCO gain, the electronic processor is configured to:
detect a first voltage output by the phase frequency detection loop when the IVCO is operated at a first frequency;
detect a second voltage output by the phase frequency detection loop when the IVCO is operated at a second frequency; and
calculate the IVCO gain based on a difference between the second voltage and the first voltage.

13. The SSPLL architecture of claim 6, wherein, to estimate the SSPD gain value, the electronic processor is configured to:
control the delay module to vary a delay applied to the output of the RPLL generator; and
calculate a change of the phase detector output over a change in phase based on the varied delay applied to the output of the RPLL generator.

14. The SSPLL architecture of claim 6, wherein the phase detector includes a sampler and a gain module.

15. A method for controlling an SSPLL architecture, the method comprising:
operating the SSPLL architecture in a phase frequency detection operating mode;
estimating, while in the phase frequency detection operating mode, an internal voltage-controlled oscillator (IVCO) gain based on a current flowing through a phase frequency detection loop;
operating the SSPLL architecture in a gain estimation loop,
estimating a sub-sampling phase detection (SSPD) gain value based an output of a phase detector;
calculating a correction value based on the IVCO gain and the SSPD gain value;
applying the correction value to the phase detector; and
operating the SSPLL architecture in an operating SSPLL loop.

16. The method of claim 15, further comprising:
operating the SSPLL architecture in the phase frequency detection operating mode by controlling a first switch, a second switch, and a third switch to an open position and controlling a fourth switch to a closed position, wherein the first switch is between a reference phase-locked loop (RPLL) generator and the phase detector, the second switch is between the phase detector and the phase frequency detection loop, the third switch is between the phase detector and an analog-digital converter (ADC), and the fourth switch is between the phase frequency detection loop and the ADC.

17. The method of claim 15, further comprising:
operating the SSPLL architecture in the gain estimation loop by controlling a first switch, a second switch, and a fourth switch to an open position and controlling a third switch to a closed position, wherein the first switch is between a reference phase-locked loop (RPLL) generator and the phase detector, the second switch is between the phase detector and the phase frequency detection loop, the third switch is between the phase detector and an analog-digital converter (ADC), and the fourth switch is between the phase frequency detection loop and the ADC.

18. The method of claim 15, further comprising:
operating the SSPLL architecture in the operating SSPLL loop by controlling a first switch and a second switch to a closed position and controlling a third switch and a fourth switch to an open position, wherein the first switch is between a reference phase-locked loop (RPLL) generator and the phase detector, the second switch is between the phase detector and the phase frequency detection loop, the third switch is between the phase detector and an analog-digital converter (ADC), and the fourth switch is between the phase frequency detection loop and the ADC.

19. The method of claim 15, wherein estimating the IVCO gain includes:
detecting a first voltage output by the phase frequency detection loop when an internal voltage controlled oscillator (IVCO) included in the phase frequency detection loop is operated at a first frequency;
detecting a second voltage output by the phase frequency detection loop when the IVCO is operated at a second frequency; and
calculating the IVCO gain based on a difference between the second voltage and the first voltage.

20. The method of claim 15, wherein estimating the SSPD gain value includes:
controlling a delay module to vary a delay applied to an output of an RPLL generator; and
calculating a change of the output of the phase detector over a change in phase based on the varied delay applied to the output of the RPLL generator.
